(19) United States
(12) Patent Application Publication
(10) Pub. No.: US 2003/0210435 A1
(43) Pub. Date: Nov. 13, 2003

(54) Color image sensor and driving method for the same

(75) Inventor: Shiro Tsunai, Kanagawa (JP)

Correspondence Address: McGinn & Gibb, PLLC, Suite 200, 8321 Old Courthouse Road, Vienna, VA, 22182-3817, US

(73) Assignee: NEC Electronics Corporation, Kawasaki (JP)

(21) Appl. No.: 10/427,917

(22) Filed: May 2, 2003

(30) Foreign Application Priority Data
May 8, 2002 (JP) 133246/2002

(51) Int. Cl. H04N 1/04; G03F 3/08

(52) U.S. Cl. 358/483; 358/518

(57) ABSTRACT

A color image sensor includes a plurality of image elements, a plurality of read gate sections, a plurality of vertical scanning charge transfer sections, and a plurality of transfer switch sections. The plurality of image elements are arranged in a matrix of rows and columns and each of the plurality of image elements generates an electric charge in response to incidence of light. The plurality of read gate sections are provided for the plurality of image elements, and each of the plurality of image elements controls transfer of the electric charge generated in a corresponding one of the plurality of image elements. Each of the plurality of vertical scanning charge transfer sections is provided for every column of the matrix to hold and transfer the electric charges transferred from a corresponding column of the plurality of read gate sections. Each of the plurality of transfer switch sections is provided for a termination section of a corresponding one of the plurality of vertical scanning charge transfer sections to control transfer of the electric charges from the corresponding vertical scanning charge transfer section. The horizontal scanning charge transfer section is provided for the plurality of transfer switch sections to hold and transfer the electric charges transferred from the plurality of vertical scanning charge transfer sections via the plurality of transfer switch sections.

### BACKGROUND OF THE INVENTION

1. Field of the Invention

The present invention relates to a color image sensor for converting a color image into an electric signal and a method of driving the color image sensor.

2. Description of the Related Art

Using a charge transfer apparatus having 1-dimensional charge-coupled elements, a read operation of a 2-dimensional color image is carried out as follows. First, white light is irradiated to a printed image and then reflected light or transmitted light is dissolved into three-color lights of the read (R), green (G) and blue (B). Next, the light of each color is received by light receiving sections of the 1-dimensional charge-coupled elements and is converted into electric charges in accordance with a quantity of the light. Next, the electric charge is transferred by a charge transfer section and is converted into an electric signal by an electric charge-voltage converter provided for an end section of the charge transfer section. Then, the electric signal is stored in a memory. After that, a charge-coupled element is relatively scanned to the printed image.

In the same way, an electric signal is generated from the white light reflected from the printed image and is stored in the memory in order. Thus, an electric signal for the printed image is obtained. After that, the electric signals of R, G and B corresponding to a same portion of the printed image are synthesized by an information processor. By synthesizing over all the portions, a color image is reproduced.

In this case, one charge transfer section corresponds to the light receiving sections for one kind of color, e.g., the red color in the 1-dimensional charge-coupled elements. Therefore, generally, three charge transfer sections are provided for three kinds of colors of R, G and B.

As described above, when an image is converted into an electric signal, the image can be reproduced in a high resolution, if the distance (hereinafter, to be referred to as a “line interval”) between a row of the light receiving sections of the 1-dimensional charge-coupled elements and another row of the light receiving sections of another 1-dimensional charge-coupled elements is small. Also, a capacity of the memory can be made less when the line interval is smaller. Therefore, the technique that can make the line interval small is demanded.

Also, when a density of the light receiving sections becomes high and the resolution becomes higher, the influence of the heat noise due to thermo electrons generated in the charge-coupled elements becomes larger. That is, when the density of the image elements becomes high, a light reception quantity per image element decreases so that a quantity of generated electrons becomes little. Therefore, a rate of thermo electrons to electrons generated based on the light becomes high relatively. The technique that can prevent the influence of thermo electrons is demanded.

Moreover, even if the light receiving section is of a high density, there is a case that the reproduced image may be a low density, depending on a use situation by a user. For example, it is a case where a printed image is first read in a reading speed priority, the printed image is confirmed, and then the printed image is read in a high minuteness. Even if the light receiving sections are arranged in the high density, the technique that can change the density of the read image is demanded.

In conjunction with the above description, a solid-state image sensor is disclosed in Japanese Laid Open Patent Application (JP-A-Showa 62-296672). In this conventional example, the solid-state image sensor is composed a horizontal transfer register of charge transfer elements. An output amplifier converts charge transferred from the horizontal transfer register into an output voltage using a floating diffusion layer. A first reset transistor resets the potential of the floating diffusion layer to a first predetermined potential. An output gate is provided between the floating diffusion layer and the horizontal transfer register. A second reset transistor resets the potential of a channel directly below a final transfer electrode of the horizontal transfer register to a second predetermined potential at a timing at which a rest operation of the first reset transistor is stopped.

Also, a color imaging apparatus is disclosed in Japanese Laid Open Patent Application (JP-A-Heisei 5-199528). The conventional color imaging apparatus is composed of sensor sections 3B, 3R and 3G which receive light through color filters, and a plurality of charge transfer register sections 11B, 11R and 11G corresponding to the respective colors. The charge transfer register sections have different areas in accordance with the difference in a maximum quantity of electric charge due to the difference in the characteristic of the spectrum of each color filter, i.e., the areas of the widths WB<WR<WG. Thus, the reduction of power consumption and the reduction of a chip area are achieved in a color linear sensor.

Also, a color image reader is disclosed in Japanese Laid Open Patent Application (JP-A-Heisei 7-264355). In the conventional color image reader, light reflected from a manuscript is separated into color component lights. Each color component light is focused on light receiving elements of line image sensors which are arranged in a vertical scanning direction on positions shifted to each other. The image is read by scanning the line image sensor in a horizontal scanning direction and by scanning the focusing position into the vertical direction. The light receiving elements of the line image sensor are arranged in the vertical scanning direction in an order of the wavelength of the spectrum characteristic of each color. The center of gravity of the sensitivity of the light receiving elements of at least two colors are shifted by a distance smaller than a sensor sampling pitch determined based on the distance between the light receiving elements in the horizontal scanning direction. Thus, a gap correction is achieved by a simple structure in the color image read apparatus having three read lines by narrowing the distance between the light receiving elements in the vertical scanning direction.

Also, a solid-state imaging apparatus is disclosed in Japanese Laid Open Patent Application (JP-A-Heisei 8-172178). The conventional solid-state imaging apparatus is composed of a row of a plurality of photoelectric conversion elements for generating a signal charge in accordance with an incident light quantity. A CCD register takes a plurality of signal charges generated by the photoelectric conversion elements row in a transfer channel formed by a first impurity diffusion layer to transfer through the transfer channel in the order. An overflow drain has a second impurity diffusion layer formed along the first impurity diffusion layer to have a low resistance and injects the signal charge discharged from said transfer channel into a predetermined node. An overflow adjustment layer has a third impurity diffusion layer which is provided between the first impurity diffusion layer and the second impurity diffusion layer and has an impurity concentration lower than the first impurity diffusion layer. In the CCD linear image sensor which has a section for discharging excess charge adjacent to the CCD register and in which the plurality of pixel elements are arranged in parallel. The distance between pixels can be narrowed. Thus, the excess signal charge more than a predetermined level can be discharged without using the overflow control electrode.

Also, a charge transfer apparatus is disclosed in Japanese Laid Open Patent Application (JP-A-Heisei 11-317514). The charge transfer apparatus of this conventional example is composed of three one-dimensional charge-coupled elements, which has a first image element row, a second image element row and a third image element row. In the charge transfer apparatus, the second image element row is arranged adjacent to the first image element row and the third image element row is arranged adjacent to the second image element row. A plurality of first read electrodes are provided between the image elements of the third image element row to the read signal charge generated in the second image element row. In this conventional example, one of three charge transfer sections is omitted. Remaining two charge transfer sections are arranged outside the three image element rows. Therefore, the line interval can be made small. Also, the linear interval can be made regular from the first image element row to the third image element row. Therefore, the printed image can be reproduced in a high resolution and the quantity of the memory can be made little.

Also, a semiconductor device manufacturing method is disclosed in Japanese Laid Open Patent Application (JP-P2000-156420A). In the conventional method, a plurality of devices are formed on a semiconductor substrate. A first insulating film is formed on the devices and a first oxide film is formed on the first insulating film. A groove is formed in a predetermined area of the first oxide film, and a resistance element is formed in the groove. A second insulating film is formed on the first oxide film and contact holes are formed in predetermined positions on the devices and the resistance element. Thus, the wiring is carried out using the contact holes.

### SUMMARY OF THE INVENTION

Therefore, an object of the present invention is to provide a color image sensor and a method of driving the color image sensor, in which an unnecessary electric charge like thermo electrons stored in the sensor can be discharged.

Also, another object of the present invention is to provide a color image sensor and a method of driving the color image sensor, in which it is possible to change a density or resolution of a read image even if image elements are arranged in a high density.

Another object of the present invention is to provide a color image sensor and a method of driving the color image sensor, in which it is not necessary to take synchronization between horizontal scanning charge-coupled elements when the horizontal scanning charge-coupled elements are plural.

Also, another object of the present invention is to provide a color image sensor and a method of driving the color image sensor, in which it is possible to achieve the above objects while restraining kinds of control clock signals or voltage pulses.

Another object of the present invention is provide a color image sensor and a method of driving the color image sensor, in which it is possible to extract an electric signal obtained by synthesizing any combination of R, G and B such as R-G, G-B, R-G-B.

In an aspect of the present invention, a color image sensor includes a plurality of image elements, a plurality of read gate sections, a plurality of vertical scanning charge transfer sections, and a plurality of transfer switch sections. The plurality of image elements are arranged in a matrix of rows and columns and each of the plurality of image elements generates an electric charge in response to incidence of light. The plurality of read gate sections are provided for the plurality of image elements, and each of the plurality of image elements controls transfer of the electric charge generated in a corresponding one of the plurality of image elements. Each of the plurality of vertical scanning charge transfer sections is provided for every column of the matrix to hold and transfer the electric charges transferred from a corresponding column of the plurality of read gate sections. Each of the plurality of transfer switch sections is provided for a termination section of a corresponding one of the plurality of vertical scanning charge transfer sections to control transfer of the electric charges from the corresponding vertical scanning charge transfer section. The horizontal scanning charge transfer section is provided for the plurality of transfer switch sections to hold and transfer the electric charges transferred from the plurality of vertical scanning charge transfer sections via the plurality of transfer switch sections.

Here, the color image sensor may further include a plurality of reset sections which are respectively provided for the termination sections of the plurality of vertical scanning charge transfer sections, and each of which discharges the electric charge in a corresponding one of the plurality of vertical scanning charge transfer sections.

Also, each of the plurality of vertical scanning charge transfer sections may include a plurality of first charge transfer sub-sections, and a plurality of second charge transfer sub-sections. Each of the plurality of first charge transfer sub-sections is provided for a corresponding one of the plurality of read gate sections for one column corresponding to the vertical scanning charge transfer section to hold and transfer the electric charge. Each of the plurality of second charge transfer sub-sections is provided between adjacent two of the plurality of first charge transfer sub-sections to transfer the electric charge transferred from one of the adjacent two and transfers to the other of the adjacent two. One of the plurality of first charge transfer sub-sections corresponding to the termination section is larger in area than remaining ones of the first charge transfer sub-sections.

Also, each of the plurality of vertical scanning charge transfer sections may include a plurality of first charge transfer sub-sections, and a plurality of second charge transfer sub-sections. Each of the plurality of first charge transfer sub-sections is provided for a corresponding one of the plurality of read gate sections for one column corresponding to the vertical scanning charge transfer section, to hold and transfer the electric charge. Each of the plurality of second charge transfer sub-sections may be provided between adjacent two of the plurality of first charge transfer sub-sections, to transfer the electric charge transferred from one of the adjacent two and transfers to the other of the adjacent two. The plurality of first charge transfer sub-sections and the plurality of second charge transfer sub-sections may transfer the electric charges based on a 2-phase charge transfer signal.

Also, each of the plurality of reset sections may discharge the electric charge remained in a corresponding one of the plurality of termination sections, immediately before the electric charge is newly transferred to the corresponding termination section of the corresponding vertical scanning charge transfer section, after the electric charge held in the corresponding termination section of the corresponding vertical scanning charge transfer section is transferred to the horizontal scanning charge transfer section.

Also, each of the plurality of reset sections may include a reset gate and a reset drain, and the reset drain is connected with a predetermined potential.

Also, the first charge transfer sub-section in the termination section for every column may have a larger capacity for holding of the electric charge than that of the other of the first charge transfer sub-sections.

Also, the first charge transfer sub-section in the termination section for every column can hold the electric charge generated by the plurality of image elements for the corresponding column.

Also, the horizontal scanning charge transfer section may include a plurality of first main charge transfer sections and a plurality of second main charge transfer section. The plurality of first main charge transfer sections are provided for the plurality of transfer switch sections to hold and transfer the electric charge. Each of the plurality of second main charge transfer section is provided between adjacent two of the plurality of first main charge transfer sections to hold the signal charge transferred from one of the adjacent two and to transfer to the other of the adjacent two. The plurality of first main charge transfer sections and the plurality of second main charge transfer section transfer sections transfer the electric charge based on a 2-phase transfer signal. The plurality of first charge transfer sub-sections and the plurality of second charge transfer sub-sections transfer the electric charges based on the charge transfer signals common to the first main charge transfer section and the second main charge transfer section, respectively.

Also, the plurality of transfer switch sections may select one of the plurality of vertical scanning charge transfer sections for the charge to be transferred from.

Also, each of the plurality of read gate sections may control a holding time of the electric charge by the corresponding image element.

Also, the vertical scanning charge transfer section may have a first well which holds the electric charge, and the horizontal scanning charge transfer section has a second well which holds the electric charge. The first well and the second well may be formed as a unit.

In another aspect of the present invention, a method of driving a color image sensor is achieved by (a) storing electric charge generated based on incident light by a plurality of image elements in a matrix; by (b) storing the electric charges transferred from a column of the matrix of the plurality of image elements by a corresponding one of a plurality of vertical scanning charge transfer sections; and by (c) converting the electric charges transferred from the plurality of vertical scanning charge transfer sections into an electric signal by a horizontal scanning charge transfer section.

Here, the (b) step may be achieved by (d) receiving the electric charges transferred from each of the columns of the plurality of image elements based on a first transfer signal by a corresponding one of the plurality of vertical scanning charge transfer sections. The storage time of the electric charge in each of the plurality of image elements is desirably controlled based on a period of the first transfer signal.

Also, the (c) step may be achieved by (e) receiving the electric charges transferred from the plurality of vertical scanning charge transfer sections based on a second transfer signal by the horizontal scanning charge transfer section. One of the plurality of vertical scanning charge transfer sections for the electric charge to be transferred from is desirably selected based on the second transfer signal.

### BRIEF DESCRIPTION OF THE DRAWINGS

FIG. 1 is a plan view showing the structure of a color image sensor according to a first embodiment of the present invention;

FIG. 2A is a cross sectional view showing the color image sensor along the line X-X′ in FIG. 1;

FIG. 2B is a diagram showing a distribution of potentials in respective sections at time T1;

FIG. 2C is a diagram showing a distribution of potentials in the sections at time T2;

FIG. 3A is a cross sectional view showing the color image sensor along the line Y-Y′ in FIG. 1;

FIG. 3B is a diagram showing a distribution of potentials in respective sections at time T3;

FIG. 3C is a diagram showing a distribution of potentials in the sections at time T4;

FIG. 3D is a diagram showing a distribution of potentials in the sections at time T5;

FIG. 4A is a cross sectional view showing the color image sensor along the line U-U′ in FIG. 1;

FIG. 4B is a diagram showing a distribution of potentials in respective sections at time T6;

FIG. 4C is a diagram showing a distribution of potentials in the sections at time T7;

FIG. 5A is a cross sectional view showing the color image sensor along the line Z-Z′ in FIG. 1;

FIG. 5B is a diagram showing a distribution of potentials in respective sections at time T8;

FIG. 5C is a diagram showing a distribution of potentials in the sections at time T9;

FIG. 6 is a cross sectional view showing the color image sensor along the line Z-Z′ in FIG. 1;

FIGS. 7A to 7E are timing charts showing the voltage pulses;

FIG. 8 is a plan view showing the structure of the color image sensor according to the second embodiment of the present invention;

FIG. 9A is a cross sectional view showing the color image sensor along the line Y-Y′ in FIG. 8;

FIG. 9B is a diagram showing a distribution of potentials in the sections; and

FIG. 10 is a plan view showing the structure of a modification of the color image sensor according to the first embodiment of the present invention.

### DESCRIPTION OF THE PREFERRED EMBODIMENTS

Hereinafter, a color image sensor of the present invention will be described with reference to the attached drawings. It should be noted that in the following embodiments, a same reference numeral is allocated to a same component.

(First Embodiment)

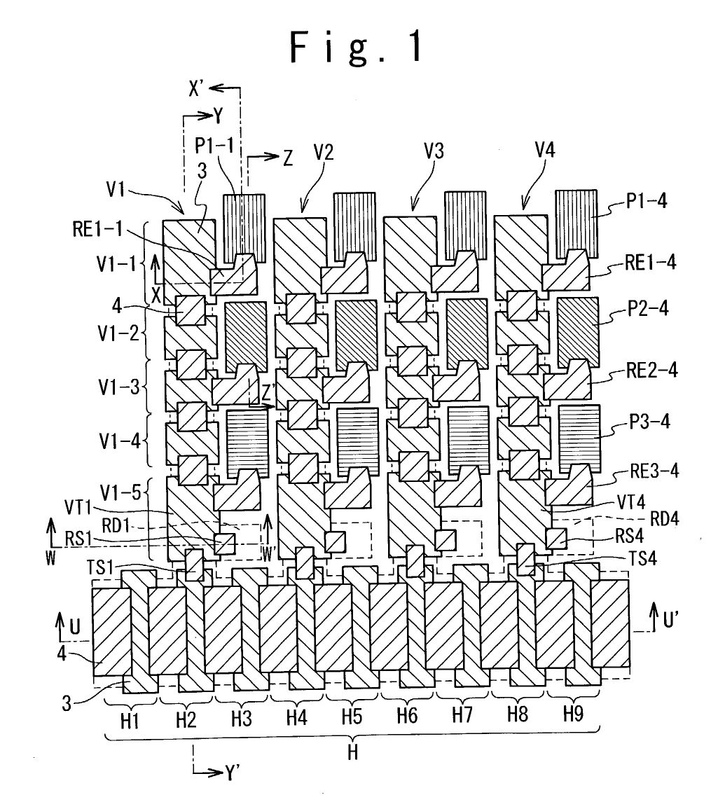

The structure of the color image sensor according to the first embodiment of the present invention will be described with reference to FIG. 1. FIG. 1 is a plan view showing the structure of the color image sensor according to the first embodiment of the present invention. The color image sensor is composed of image elements P1-1 to P3-4, read gates RE1-1 to RE3-4, vertical scanning charge transfer sections V1 to V4, a horizontal scanning charge transfer section H, reset gates RS1 to RS4, reset drains RD1 to RD4 and transfer switches TS1 to TS4. The color image sensor in the first embodiment is formed on a P-type substrate. However, the present invention may be achieved by forming the P-type well on an N-type substrate.

Here, in the specification of the drawings of the present application, the structure of a wiring line to each gate electrode, a through-hole in a wiring line connection section, and a color filter are omitted. Also, a metal film 22 such as an aluminum film used for light shielding is omitted in FIGS. 1, 8, and 10.

Next, the structure of each section will be described. The image elements P1-1 to P1-4 are arranged in a predetermined interval in a row direction parallel to the horizontal scanning charge transfer section H and in a column direction orthogonal to the horizontal scanning charge transfer section H. The image elements P1-1 to P1-4 are referred to as a first row of the image elements. In the same way, the image elements P2-1 to p2-4 are arranged in the predetermined interval in the row direction on the side nearer the horizontal scanning charge transfer section H than the first row of the image elements. The image elements P3-1 to P3-4 are arranged in the predetermined interval in the row direction on the side nearer the horizontal scanning charge transfer section H than the second row of image elements. That is, the image elements P1-1 to P3-4 are arranged in a matrix. FIG. 1 shows an example in which the image elements P1-1 to P3-4 are arranged in the matrix of three rows and four columns. However, the number of image elements is not limited to these values.

Each of the image elements P1-1 to P3-4 receives light through a color filter for any of the three primary colors and generates electrons and accumulates the generated electrons as electric charge. A photodiode is exemplified as each image element. In the color image sensor in this embodiment, the color filters of the three primary colors are put above the rows of the image elements P1-1 to P3-4 for respective rows.

Each of the read gates RE1-1 to RE1-4 as read gate sections are arranged to be operatively connected to a corresponding one of the image elements P1-1 to P3-4 of the first row and a corresponding one of the vertical scanning charge transfer sections V1 to V4. In the same way, each of the read gates RE2-1 to RE2-4 is arranged to be operatively connected to a corresponding one of the image elements P2-1 to P2-4 of the second row and a corresponding one of the vertical scanning charge transfer sections V1 to V4, and each of the read gates RE3-1 to R3-4 is arranged to be operatively connected to a corresponding one of the image elements P3-1 to P3-4 of the third row and a corresponding one of the vertical scanning charge transfer sections V1 to V4. Each of the read gates RE1-1 to RE3-4 selectively transfers the electric charge stored or held in the corresponding one of the image elements P1-1 to P3-4 to the corresponding one of the vertical scanning charge transfer sections V1 to V4 based on voltage pulses φ_{SH} as first transfer signals. The voltage pulse φ_{SH} is different for every row. Also, the voltage pulse φ_{SH} may be set to be different for every image element.

In FIG. 1, each of the read gates RE1-1 to RE3-4 is arranged to be operatively connected to the corresponding one of the image elements P1-1 to P3-4 on the side of the horizontal scanning charge transfer section H to be described later in detail. However, the read gate may be arranged on the side of a corresponding one of the vertical scanning charge transfer sections V1 to V4. In this case, the interval between the rows of the first to third rows can be decreased, resulting in increase of an image element density.

Each of the vertical scanning charge transfer sections V1 to V4 is arranged to be operatively connected to a corresponding one of the columns of the read gates RE1-1 to RE3-4 and a corresponding one of the transfer switches TS1 to TS4. Each of the vertical scanning charge transfer sections V1 to V4 is provided in a direction orthogonal to the direction of the horizontal scanning charge transfer section H and extends along a corresponding column of the image elements P1-1 to P3-4. Each of the vertical scanning charge transfer sections V1 to V4 transfers the electric charges, which have been transferred from a corresponding one of the columns of the image elements P1-1 to P3-4 through a corresponding one of the columns of the read gates RE1-1 to RE3-4, to the horizontal scanning charge transfer section H based on a voltage pulse φ₁ and a voltage pulse φ₂ as the charge transfer signals. The electric charge is stored in the termination portion VT1 to VT4 of each of the vertical scanning charge transfer section V1 to v4 on the side of the horizontal scanning charge transfer section H.

The vertical scanning charge transfer sections V1 to V4 have the same structure. Therefore, the vertical scanning charge transfer section V1 will be described. The vertical scanning charge transfer section V1 has vertical scanning charge-coupled elements V1-1, V1-3, and V1-5 as first vertical scanning charge transfer sub-sections and vertical scanning charge-coupled elements V1-2, and V1-4 as second vertical scanning charge transfer sub-sections. The vertical scanning charge-coupled elements V1-2 and V1-4 are controlled based on the voltage pulse φ₂. The vertical scanning charge-coupled element V1-2 or V1-4 is composed of a portion having a first layer polysilicon electrode 3 and a portion having a second layer polysilicon electrode 4. The vertical scanning charge-coupled element V1-2 receives the electric charge transferred from the vertical scanning charge-coupled element V1-1, stores and transfers to the vertical scanning charge-coupled element V1-3. In the same way, the vertical scanning charge-coupled element V1-4 receives, stores and transfers the electric charge of the vertical scanning charge-coupled element V1-3 to the vertical scanning charge-coupled element V1-5. In the same way, the vertical scanning charge-coupled elements V1-1, V1-3, and V1-5 are controlled based on the voltage pulse φ₁. Each of the vertical scanning charge-coupled elements V1-3 and V1-5 are composed of a portion having the first layer polysilicon electrode 3 and a portion having the second layer polysilicon electrode 4. The vertical scanning charge-coupled element V1-1 has a portion having the first layer polysilicon electrode 3 but does not have a portion having the second layer polysilicon electrode 4. Instead, the vertical scanning charge-coupled element V1-1 is operatively connected with the corresponding read gate RE1-1.

It should be noted that the portion having the first polysilicon electrode 3 of the vertical scanning charge-coupled element V1-5 is referred to as a vertical scanning termination element VT1. The vertical scanning termination element VT1 is formed to have a sufficiently large area such that a CCD-N-type well 13 under the first layer polysilicon electrode 3 of the vertical scanning charge-coupled element V1-5 can store and hold all of the electric charges transferred from a corresponding one of the columns of the image elements P1-1 to P3-4.

The vertical scanning charge-coupled element V1-1 receives, stores and transfers the electric charge transferred from the image element P1-1 to the vertical scanning charge-coupled element V1-2. The vertical scanning charge-coupled element V1-3 receives, stores and transfers the electric charge transferred from the image element P2-1 and the vertical scanning charge-coupled element V1-2 to the vertical scanning charge-coupled element V1-4. The vertical scanning charge-coupled element V1-5 receives, stores and transfers the electric charge transferred from the image element P1-3 and the vertical scanning charge-coupled element V1-4 to the horizontal scanning charge transfer section H.

In the vertical scanning charge transfer section V1, the respective elements are arranged in order of the vertical scanning charge-coupled element V1-1 operatively connected to the read gate RE1-1/the vertical scanning charge-coupled element V1-2/the vertical scanning charge-coupled element V1-3 operatively connected to the read gate to RE2-1/the vertical scanning charge-coupled element V1-4/the vertical scanning charge-coupled element V1-5 operatively connected to the read gate RE3-1. The vertical scanning charge-coupled element V1-5 is arranged to be operatively connected to the transfer switch TS1. The vertical scanning charge transfer section V1 transfers the electric charge to the vertical scanning termination element VT1 based on a 2-phase drive method of the voltage pulses φ₁ and φ₂.

Each of the transfer switches TS1 to TS4 as transfer switch sections is arranged to be operatively connected to a corresponding one of the vertical scanning charge transfer sections V1 to V4 and the horizontal scanning charge transfer section H. The transfer switch TS1 selectively transfers the electric charge from the vertical scanning charge-coupled element V1-5 in the vertical scanning charge transfer section V1 to the horizontal scanning charge transfer section H based on a voltage pulse φ_{TR} as a second transfer signal.

The horizontal scanning charge transfer section H extends in the direction orthogonal to the plurality of vertical scanning charge transfer sections V1 to V4. That is, the horizontal scanning charge transfer section H receives the electric charges from the vertical scanning charge transfer sections V1 to V4 through the transfer switches TS1 to TS4. The electric charges transferred from the vertical scanning charge transfer sections V1 to v4 are scanned to the horizontal scanning direction based on the voltage pulse φ₁ and the voltage pulse φ₂, and an electric charge-voltage conversion is carried out to the electric charges. The horizontal scanning charge transfer section H is composed of horizontal scanning charge-coupled elements H1 to H9 and a charge detecting section (not shown) which carries out the electric charge-voltage conversion to the transferred electric charge. The charge detecting section is connected with a termination section.

Each of the horizontal scanning charge-coupled elements H1, H3, H5, H7 and H9 is controlled based on the voltage pulse φ₁. Each of the horizontal scanning charge-coupled elements H1, H3, H5, H7 and H9 is composed of a portion having a first layer polysilicon electrode 3 and a portion having a second layer polysilicon electrode 4. Each of the horizontal scanning charge-coupled elements H3, H5, H7 and H9 receives, stores and transfers the electric charge transferred from a corresponding one of the horizontal scanning charge-coupled elements H2, H4, H6, and H8 to the next one of the horizontal scanning charge-coupled elements H4, H6, H8 and H10 (not shown). Each of the horizontal scanning charge-coupled elements H2, H4, H6 and H8 is operatively connected to a corresponding one of the transfer switches TS1 to TS4, and is controlled based on the voltage pulse φ₂. Each of the horizontal scanning charge-coupled elements H2, H4, H6 and H8 is composed of a portion having a first layer polysilicon electrode 3 and a portion having a second layer polysilicon electrode 4. Each of the horizontal scanning charge-coupled element H2, H4, H6 and H8 receives, stores and transfers the electric charge transferred from a corresponding one of the horizontal scanning charge-coupled elements H1, H3, H5, and H7 to the next one of the horizontal scanning charge-coupled elements H3, H5, H7 and H9. Also, each of the horizontal scanning charge-coupled elements H2, H4, H6 and H8 receives, stores and transfers the electric charge transferred from a corresponding one of the vertical scanning charge transfer sections V1 to V4 to the next one of the horizontal scanning charge-coupled elements H3, H5, H7 and H9. That is, the horizontal scanning charge transfer section H transfers the electric charge to the charge detecting section based on the 2-phase drive method of the voltage pulses φ₁ and φ₂.

Each of the reset gates RS1 to RS4 as a part of reset sections is arranged to be operatively connected to the termination section of a corresponding one of the vertical scanning charge transfer sections V1 to V4 and a corresponding one of the reset drains RD1 to RD4. The reset gate RDi (i=1, 2, 3, 4) selectively discharges unnecessary electric charge, such as thermo electrons and electrons left after the output operation of electrons to the horizontal scanning charge transfer section H, stored in the vertical scanning electric charge termination element Vti of the corresponding vertical scanning charge transfer section to the corresponding reset drain RDi based on the voltage pulse φ_{R17}.

Each of the reset drains RD1 to RD4 as another part of the reset section discharges the unnecessary electric charge which has been discharged via the corresponding reset gate outside. The reset drain RDi is connected with the 12-V power supply through a wiring line, in this embodiment.

The charge detecting section (not shown) is connected with the termination section (not shown) of the horizontal scanning charge transfer section H. The charge detecting section converts a transferred electric charge into an electric signal like a voltage signal and outputs it. As such an electric charge converting section, conventionally known various means such as a floating diffusion detector, and a floating gate detector can be used.

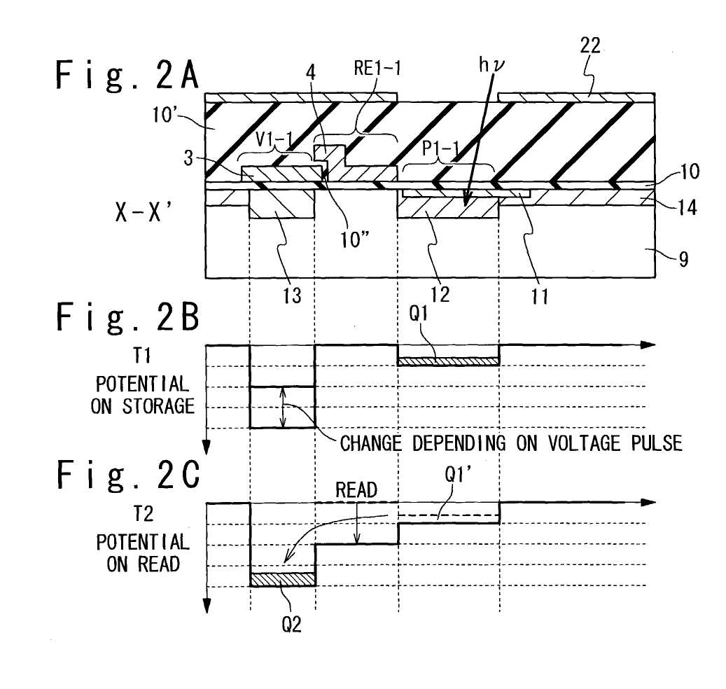

Next, the cross section of the color image sensor along the line X-X′ section in FIG. 1 will be described with reference to FIG. 2A. FIG. 2A is a cross section of the color image sensor along the lines X-X′ section in FIG. 1, i.e., the cross section from the image element P1-1 to the vertical scanning charge-coupled element V1-1. In this case, the cross section from one of the other image elements to a corresponding one of the vertical scanning charge-coupled elements is same as FIG. 2A. The color image sensor is composed of the image element P1-1, the read gate RE1-1, and the vertical scanning charge-coupled element V1-1, as shown in the cross section, and a P⁺-type diffusion layer 14 is formed to surround them.

A thin oxide film 10 functioning a gate oxide film is formed on the p-type substrate 9. The first polysilicon layer 3 of the vertical scanning charge-coupled element V1-1 and the second polysilicon layer 4 for the read gate RE1-1 are formed on the oxide film 10. An oxide film 10′ functioning as a passivation film is formed on the oxide film 10 to cover the first polysilicon layer 3 and the second polysilicon layer 4. A light shielding film 22 is formed to cover the oxide film 10′ in a region other than a region corresponding to the image element P1-4.

As shown in FIG. 2A, in the p-type substrate 9, the p⁺-type diffusion layer 14 is formed for the image element P1-1 in a region on the side opposite to the read gate RE1-1. An N-type diffusion layer 12 is formed in the P-type substrate 9 to have a deeper depth than the P⁺-type diffusion layer 14. The N-type diffusion layer 12 is formed to contact an end of the P⁺-type diffusion layer 14 in a transverse direction parallel to the surface of the p-type substrate 9. A P-type diffusion layer 11 is formed in the N-type diffusion layer 12 to have a shallower depth than the layer 12. The P-type diffusion layer 11 extends to the inside of the P⁺-type diffusion layer 14 in the transversal direction. However, the P-type diffusion layer 11 does not reach the end of the N-type diffusion layer 12 in a direction opposite to the transversal direction. In this way, the image element P1-1 has a P-N-P structure in the depth direction. Thus, the P-type diffusion layer 11 and the N-type diffusion layer 12 forms a photodiode which generates electrons as electric charge in accordance with a quantity of incident light. The generated electrons are stored in the N-type diffusion layer 12.

The read gate RE1-1 is composed of the second layer polysilicon electrode 4 and the oxide film 10 on the P-type substrate 9. The second layer polysilicon electrode 4 of the read gate RE1-1 is formed on the oxide film 10 which covers the P-type substrate 9, and functions as a gate electrode. The one end of the second layer polysilicon electrode 4 extends onto the P-type diffusion layer 11 of the image element P1-1 through the oxide film 10 in the transversal direction. The other end of the second layer polysilicon electrode 4 extends to a position near the first polysilicon layer 3 for the vertical scanning charge-coupled element V1-1 in the direction opposite to the transversal direction, and extends upwardly and then extends in the direction opposite to the transversal direction to cover a part of the first layer polysilicon electrode 3 for the vertical scanning charge-coupled element V1-1 through the oxide film 10″ which insulates the second layer polysilicon electrode 4 and the first layer polysilicon electrode 3. The read gate RE1-1 controls the transfer of the electric charge stored in the image element P1-1 based on the voltage pulse φ_{SH} supplied to the second layer polysilicon electrode 4. That is, when the voltage pulse φ_{SH} is in an ON state, the potential well of the read gate RE1-1 becomes deep so that the electric charge stored in the image element P1-1 becomes removable to a CCD-N-type well 13 of the vertical scanning charge-coupled element V1-1.

The vertical scanning charge-coupled element V1-1 has the first layer polysilicon electrode 3, the oxide film 10 and the CCD-N-type well 13. The CCD-N-type well 13 of the vertical scanning charge-coupled element V1-1 is formed in the P-type substrate 9 in a predetermined depth in the depth direction and in a predetermined area not to extend outside the electrode 3 in the transversal direction. The first layer polysilicon electrode 3 of the vertical scanning charge-coupled element V1-1 is formed to have a function of the gate electrode and to cover the CCD-N-type well 13 through the oxide film 10. A part of the first layer polysilicon electrode 3 is covered by the second layer polysilicon electrode 4 of the read gate RE1-1 through the oxide film 10″. The vertical scanning charge-coupled element V1-1 controls the potential well of the CCD-N-type well 13 based on the voltage pulse φ₁ supplied to the first layer polysilicon electrode 3. That is, when the voltage pulse φ₁ is in an ON state, the CCD-N-type well 13 becomes deep so that the electric charge generated in the image element P1-1 can be received by the CCD-N-type well 13 through the read gate RE1-1.

It should be noted that the CCD-N-type wells 13 in this embodiment are formed in the same process. Especially, the CCD-N-type wells 13 for the vertical scanning charge-coupled elements V1-1 to V1-5 are formed at a time in a same process under a same condition. Also, in this embodiment, the read control of the electric charge from the image element P1-1 to the vertical scanning charge-coupled element V4-1 is carried out using the second layer polysilicon electrode 4. However, the present invention may be implemented by exchanging the first layer polysilicon electrode 3 and the second layer polysilicon electrode 4.

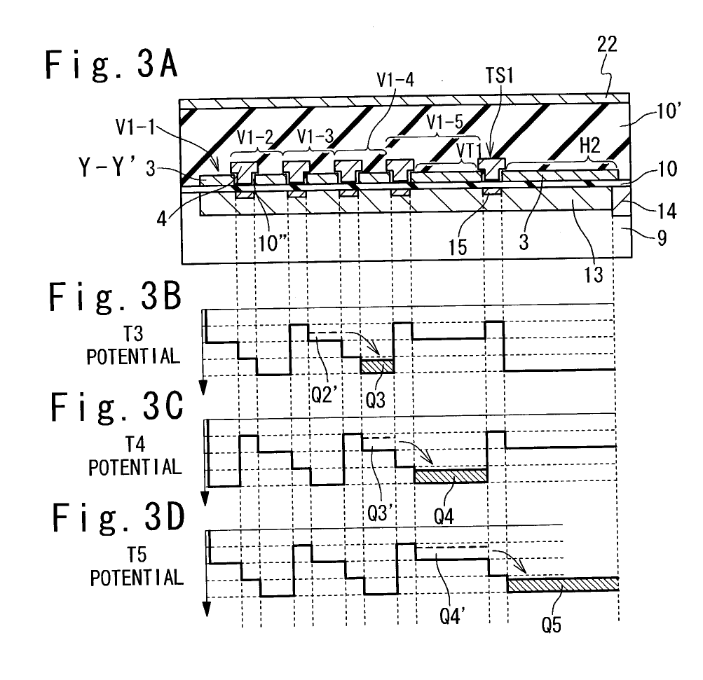

Next, the cross section along the line Y-Y′ in FIG. 1 will be described with reference to FIG. 3A. FIG. 3A is a cross sectional view showing the vertical scanning charge transfer section V1 from the vertical scanning charge-coupled element V1-1 to the horizontal scanning charge transfer section H along the line Y-Y′ in FIG. 1. The vertical scanning charge-coupled element V1-1, the vertical scanning charge-coupled element V1-2, the vertical scanning charge-coupled element V1-3, the vertical scanning charge-coupled element V1-4, the vertical scanning charge-coupled element V1-5, the transfer switch TS4, and the horizontal scanning charge-coupled element H2 are arranged to operatively connected one after another in this order. The whole surface of the vertical scanning charge transfer section V1 is covered by the oxide film 10′ and the light shielding film 22 formed on the oxide film 10′.

The vertical scanning charge-coupled element V1-1 has the structure shown in FIG. 2A. However, the first layer polysilicon electrode 3 of the vertical scanning charge-coupled element V1-1 is covered by the second layer polysilicon electrode 4 for the vertical scanning charge-coupled element V1-2 through the oxide film 10″ in an one end portion of the first layer polysilicon electrode 3 on the side of the vertical scanning charge-coupled element V1-2. The vertical scanning charge-coupled element V1-1 stores the electric charge transferred from the image element P1-1 in the CCD-N-type well 13 under the first layer polysilicon electrode 3. Then, when the voltage pulse φ₁ in an OFF state, the CCD-N-type well 13 becomes deep so that the transfer of the stored electric charge to the vertical scanning charge-coupled element V1-2 becomes possible.

The vertical scanning charge-coupled element V1-2 or V1-4 receives the electric charge transferred from the vertical scanning charge-coupled element V1-1 or V1-3 and transfers to the CCD-N-type well 13 under the first layer polysilicon electrode 3 for the vertical scanning charge-coupled element V1-2 or V1-4 through the N-type well 15 under the second layer polysilicon electrode 4 for the vertical scanning charge-coupled element V1-2 or V1-4. Here, the vertical scanning charge-coupled element V1-2 has an N-type well 15, a CCD-N-type well 13 and the oxide film 10 under the second layer polysilicon electrode 4. The CCD-N-type well 13 under the second layer polysilicon electrode 4 is same as the CCD-N-type well 13 of the vertical scanning charge-coupled element V1-1. However, in this case, the N-type well 15 is formed in the surface portion of the CCD-N-type well 13.

The N-type well 15 under the second layer polysilicon electrode 4 is provided in the film thickness thinner than the CCD-N-type well 13 in the depth direction of the P-type substrate 9 and in an area equal to or rather larger the CCD-N-type well 13 in the transversal direction. The second layer polysilicon electrode 4 is formed on the oxide film 10 and has the function of the gate electrode. One end portion of the electrode 4 covers one end portion of the first layer polysilicon electrode 3 of the vertical scanning charge-coupled element V1-1 through the oxide film 10″. The other end portion of the electrode 4 covers one end portion of the first layer polysilicon electrode 3 of the vertical scanning charge-coupled element V1-2 or V1-4 through the oxide film 10″.

The N-type well 15 in this embodiment is controlled by using the first layer polysilicon electrode 3 as a mask and implanting P-type impurity material such as boron such that the N-type well 15 is shallower than the CCD-N-type well 13. The N-type wells 15 are formed at a time in a same process under a same condition.

The vertical scanning charge-coupled element V4-2 or V4-4 has the CCD-N-type well 13 and the oxide film 10 under the first layer polysilicon electrode 3. The CCD-N-type well 13 under first layer polysilicon electrode 3 is same as that of the vertical scanning charge-coupled element V1-1. The first layer polysilicon electrode 3 is formed on the oxide film 10 and has the function of a gate electrode. One end portion of the first layer polysilicon electrode 3 is covered by the second layer polysilicon electrode 4 of the vertical scanning charge-coupled element V1-2 or V1-4 through the oxide film 10″, and the other end portion thereof is covered by the second layer polysilicon electrode 4 of the vertical scanning charge-coupled element V1-3 or V1-5 through the oxide film 10″.

The vertical scanning charge-coupled element V1-2 or V1-4 controls the transfer of the electric charge from the vertical scanning charge-coupled element V1-1 or v1-3 based on the voltage pulse φ₂ supplied to the second layer polysilicon electrode 4 and the first layer polysilicon electrode 3. That is, when the voltage pulse φ₂ is in the ON state, the N-type well 15 and CCD-N-type well 13 in the vertical scanning charge-coupled element V4-2 or V4-4 become deeper. As a result, the electric charge of the vertical scanning charge-coupled element V1-1 or V1-3 can move to the CCD-N-type well 13 under the first layer polysilicon electrode 3 of the vertical scanning charge-coupled element V1-2 or V1-4 beyond the potential wall of the N-type well 15 of the vertical scanning charge-coupled element V1-2 or v1-4.

The vertical scanning charge-coupled element V1-3 or V1-5 receives the electric charge transferred from the vertical scanning charge-coupled element V1-2 or V1-4 by the CCD-N-type well 13 under the first layer polysilicon electrode 3 of the element V1-3 or V1-5 through the N-type well 15 of the vertical scanning charge-coupled element V1-3 or V1-5. The electric charge is transferred to the vertical scanning charge-coupled element V1-4 or the horizontal scanning charge transfer section H. Here, the vertical scanning charge-coupled element V1-3 or V1-5 has the N-type well 15, the CCD-N-type well 13 and the oxide film 10 under the second layer polysilicon electrode 4. The N-type well 15 and the CCD-N-type well 13 under the second layer polysilicon electrode 4 are same as those of the vertical scanning charge-coupled element V1-2. The second layer polysilicon electrode 4 is same as that of the vertical scanning charge-coupled element V1-2. However, the one end portion of the covers one end portion of the first layer polysilicon electrode 3 of the vertical scanning charge-coupled element V1-2 or V1-4 through the oxide film 10″ and the other end portion covers the one end portion of the first layer polysilicon electrode 3 of the vertical scanning charge-coupled element V1-3 or V1-5 through the oxide film 10″.

The vertical scanning charge-coupled element V1-3 or V1-5 has the CCD-N-type well 13 and the oxide film 10 under the first layer polysilicon electrode 3. The CCD-N-type well 13 under the first layer polysilicon electrode 3 is same as the vertical scanning charge-coupled element V1-1. The first layer polysilicon electrode 3 is same as the vertical scanning charge-coupled element V1-1. However, the one end portion covers the second layer polysilicon electrode 3 of the vertical scanning charge-coupled element V1-5 is covered by the second layer polysilicon electrode 3 of the vertical scanning charge-coupled element V1-4 through the oxide film 10″, and the other end portion is covered by the transfer switch TS1 through the oxide film 10″.

The vertical scanning charge-coupled element V1-3 or V1-5 controls the transfer of the electric charge from the vertical scanning charge-coupled element V1-2 or V1-4 based on the voltage pulse φ₁ supplied to the second layer polysilicon electrode 4 and the first layer polysilicon electrode 3. That is, when the voltage pulse φ₁ is in the ON state, the potentials well of the N-type well 15 and the CCD-N-type well 13 in the vertical scanning charge-coupled element V1-3 or V1-5 becomes deep. Therefore, the electric charge of the vertical scanning charge-coupled element V1-2 or V1-4 can move to the CCD-N-type well 13 under the first layer polysilicon electrode 3 beyond the potential wall of the N-type well 15 of the vertical scanning charge-coupled element V1-3 or V1-5.

Also, the vertical scanning charge-coupled element V1-3 or V1-5 controls the potential of the CCD-N-type well 13 based on the voltage pulse φ₁ supplied to the first layer polysilicon electrode 3, as in the vertical scanning charge-coupled element V1-1. That is, when the voltage pulse φ₁ is in the ON state, the potential well of the CCD-N-type well 13 becomes deep and can receive the electric charge generated in the image element P2-1 or P3-1 by the CCD-N-type well 13 through the read gates RE2-1 or RE3-1.

Then, the vertical scanning charge-coupled element V1-3 or V1-5 stores the electric charge transferred from the image element P2-1 or P3-1 in the CCD-N-type well 13. When the voltage pulse φ₁ is in the OFF state, the potential well of the CCD-N-type well 13 becomes shallow and the stored electric charge can be transferred to the vertical scanning charge-coupled element V1-4 or the horizontal scanning charge-coupled element H2.

The transfer switch TS1 has the same structure as a portion of the vertical scanning charge-coupled element V1-2 or V1-4 having the second layer polysilicon electrode 4. However, the one end portion of the second layer polysilicon electrode 4 of the transfer switch TS1 is connected with the first layer polysilicon electrode 3 of the vertical scanning charge-coupled element V1-5 through the oxide film 10″. The other ends is connected with the first layer polysilicon electrode 3 of the horizontal scanning charge-coupled element H2 in the horizontal scanning charge transfer section H through the oxide film 10″.

The transfer switch TS1 controls the transfer of the electric charge of the vertical scanning charge-coupled element V1-5 based on the voltage pulse φ_{TR} supplied to the second layer polysilicon electrode 4. That is, when the voltage pulse φ_{TR} is in the ON state, the potential well of the N-type well 15 in the transfer switch TS1 become shallow so that the electric charge of the vertical scanning charge-coupled element V1-5 can move to the CCD-N-type well 13 of the horizontal scanning charge-coupled element H2.

The horizontal scanning charge-coupled element H2, H4, H6 or H8 of the horizontal scanning charge transfer section H has structure like a portion having the first layer polysilicon electrode 3 of the vertical scanning charge-coupled element V1-2 or V1-4. In this case, the one end portion of the first layer polysilicon electrode 3 of the horizontal scanning charge-coupled element H2, H4, H6 or H8 is connected with the second layer polysilicon electrode 4 of the transfer switch TS1, TS2, Ts3 or TS4 through the oxide film 10″.

The horizontal scanning charge-coupled element H2 controls the potential of the CCD-N-type well 13 based on the voltage pulse φ₂ supplied to the first layer polysilicon electrode 3. That is, when the voltage pulse φ₂ is in the ON state, the potential well of the CCD-N-type well 13 becomes deep so that the electric charge stored in the vertical scanning charge-coupled element V1-5 can be received by the CCD-N-type well 13 through transfer switch TS1.

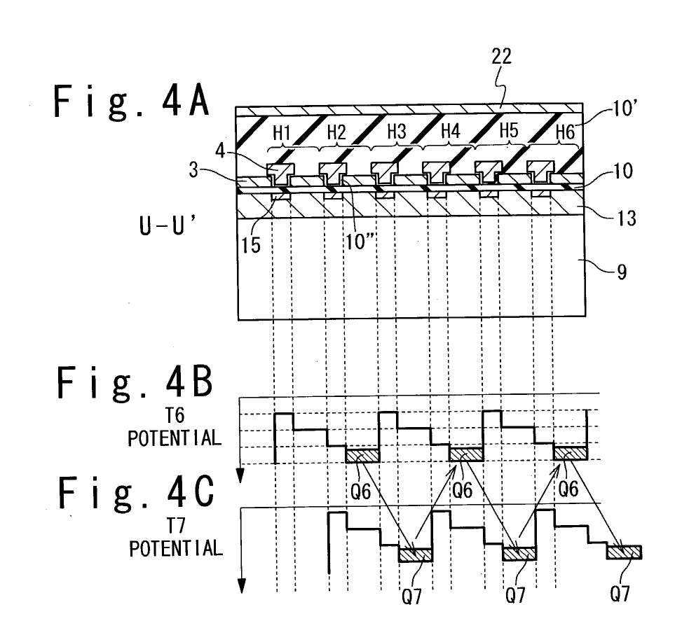

Next, the U-U′ section in FIG. 1 will be described with reference to FIG. 4A. FIG. 4A is a diagram showing the structure of the U-U′ section in FIG. 1, i.e., the cross section of the horizontal scanning charge transfer section H. In FIG. 4A, some of the horizontal scanning charge-coupled elements of the horizontal scanning charge transfer section H are omitted.

The horizontal scanning charge transfer section H is composed of a first type of the horizontal scanning charge-coupled elements H1, H3, H5, H7 and H9 and a second type of the horizontal scanning charge-coupled elements H2, H4, H6 and H8. The surface of the horizontal scanning charge transfer section H is covered by the oxide film 10″ having a function as a passivation film, and the light shielding film 22 is formed on the oxide film 10′. The CCD-N-type wells 13 in this embodiment are formed at a time in a same process under a same condition. Especially, the CCD-N-type well 13 for the horizontal scanning charge-coupled elements are formed at a time in the same process and the same condition. The CCD-N-type well 13 may be formed at the same time as the CCD-N-type well 13 for the vertical scanning charge-coupled elements. In the case, the number of processes can be decreased.

Each of the first type of the horizontal scanning charge-coupled element H1, H3, H5, H7 and H9 has the structure similar to the vertical scanning charge-coupled element V1-2 or V1-4. However, the one end portion of the first layer polysilicon electrode 3 of the horizontal scanning charge-coupled element of the first type is covered by the second layer polysilicon electrode 4 of a corresponding one of the horizontal scanning charge-coupled elements H1, H3, H5, H7 and H9 of the first type through the oxide film 10″, and the other end thereof is covered by the second layer polysilicon electrode 4 of another corresponding one of the horizontal scanning charge-coupled elements H2, H4, H6, and H8 of the second type covers through the oxide film 10″. Also, the one end portion of the second layer polysilicon electrode 4 of the other corresponding element covers the one end portion of the first layer polysilicon electrode 3 of the horizontal scanning charge-coupled elements of the first type through the oxide film 10″, and the other end portion covers the one end portion of the first layer polysilicon electrode 3 of the horizontal scanning charge-coupled element 8 through the oxide film 10″.

The horizontal scanning charge-coupled element H1, H3, H5, H7 and H9 of the second type controls the transfer of the electric charge by the horizontal scanning charge-coupled element H2, H4, H6, and H8 based on the voltage pulse φ₁ supplied to the second layer polysilicon electrode 4 and the first layer polysilicon electrode 3. That is, when the voltage pulse φ₁ is in the ON state, the potential wells of the N-type well 15 and CCD-N-type well 13 in the horizontal scanning charge-coupled element H1, H3, H5, H7 or H9 become deep. Therefore, the electric charge of the horizontal scanning charge-coupled element H2, H4, H6, and H8 can remove to the CCD-N-type well 13 beyond the potential wall of the N-type well 15 of the horizontal scanning charge-coupled element H1, H3, H5, H7 and H9. Also, when the voltage pulse φ₁ is in the OFF state, the potential well of the CCD-N-type well 13 becomes shallow so that the stored electric charge can be transferred to the horizontal scanning charge-coupled element H2, H4, H6, and H8.

The horizontal scanning charge-coupled element H2, H4, H6, and H8 has the structure similar to that of the vertical scanning charge-coupled element V1-3 or V1-5. In this case, the second layer polysilicon electrode 4 of the horizontal scanning charge-coupled element H2, H4, H6, and H8 covers the one end portion of the first layer polysilicon electrode 3 of the horizontal scanning charge-coupled element H2, H4, H6, and H8 through the oxide film 10″, and the second layer polysilicon electrode 4 of the horizontal scanning charge-coupled element H1, H3, H5, H7, and H9 covers the other end portion through the oxide film 10″. Also, the one end portion of the second layer polysilicon electrode 4 covers the one end portion of the first layer polysilicon electrode 3 of the horizontal scanning charge-coupled element H2, H4, H6, and H8 through the oxide film 10″, and the other end portion covers the one end portion of the first layer polysilicon electrode 3 of the horizontal scanning charge-coupled element H1, H3, H5, H7, and H9 through the oxide film 10″.

The horizontal scanning charge-coupled element 8 controls the transfer of the electric charge by the horizontal scanning charge-coupled element H1, H3, H5, H7, and H9 based on the voltage pulse φ₂ supplied to the second layer polysilicon electrode 4 and the first layer polysilicon electrode 3. That is, when the voltage pulse φ₂ is in the ON state, the potential wells of the N-type well 15 and the CCD-N-type well 13 in the horizontal scanning charge-coupled element H2, H4, H6, and H8 becomes deep. Therefore, the electric charge of the horizontal scanning charge-coupled element H1, H3, H5, H7, and H9 can move to the CCD-N-type well 13 beyond the wall of the N-type well 15 of the horizontal scanning charge-coupled element H2, H4, H6, and H8. Also, when the voltage pulse φ₂ is in the OFF state, the potential well of the CCD-N-type well 13 becomes shallow so that the stored electric charge can be transferred to the horizontal scanning charge-coupled element H1, H3, H5, H7, and H9.

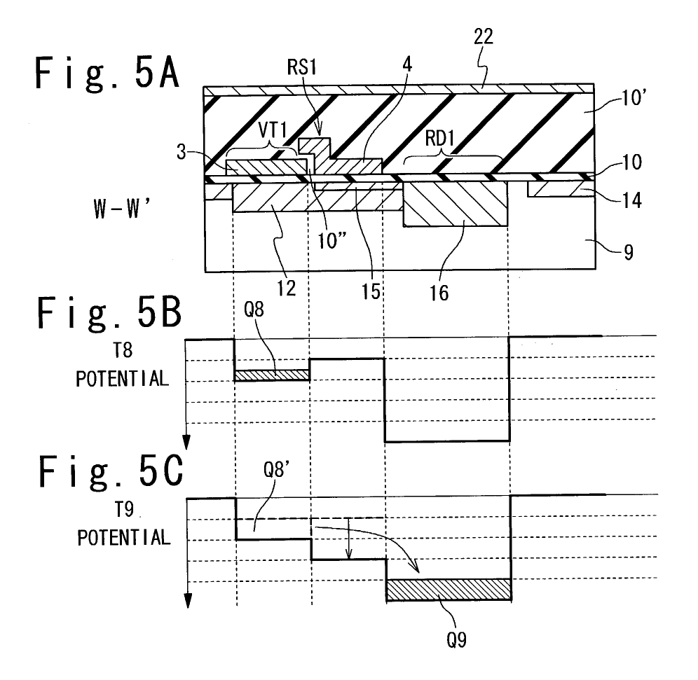

Next, W-W′ section in FIG. 1 will be described with reference to FIG. 5A. FIG. 5A is a diagram showing the structure of W-W′ section in FIG. 1, i.e., the section from the vertical scanning termination element VT1 to the reset drain RD1. The cross section is composed of the vertical scanning termination element VT1, the reset gate RS1 and the reset drain RD1. The surface is covered by the oxide film 10″ having a function as the passivation film, and the light shielding film 22 is formed on the surface of the oxide film 10′.

The vertical scanning termination element VT1 is a part of the vertical scanning charge-coupled element V1-5 where there is the first layer polysilicon electrode 3 and is as described above.

The reset gate RS1 has the structure similar to a part of the vertical scanning charge-coupled element V1-3 or V1-5 where there is the second layer polysilicon electrode 4. In this case, the one end portion of the second layer polysilicon electrode 4 in the reset gate RS1 covers the one end portion of the first layer polysilicon electrode 3 of the vertical scanning termination element VT1, and the other end portion extends to the reset drain RD1 through the oxide film 10″. Also, the vertical scanning termination element VT1 and the CCD-N-type well 13 in the reset gate RS1 are operatively connected with each other.

The reset gate RS1 controls the transfer of the electric charge of the vertical scanning termination element VT1 based on the voltage pulse φ_{R} supplied to the second layer polysilicon electrode 4. That is, when the voltage pulse φ_{R} is the ON state, the potential well of the N-type well 15 in the reset gate RS1 become deep so that the electric charge stored in the vertical scanning termination element VT1 can move to the reset drain 20.

The reset drain RD1 contains an N⁺-type diffusion layer 16. The N⁺-type diffusion layer 16 is provided in a predetermined depth (the film thickness) in the direction of the depth of P-type substrate 9 to have a predetermined area in the direction parallel to the surface of P-type substrate 9 in the surface of the P-type substrate 9. The N⁺-type diffusion layer 16 is connected with the N-type well 15 and the N-type diffusion layer 12. The surface of the reset drain RD1 is covered by the oxide film 10 and the oxide film 10′. The reset drain RD1 sends the transferred electric charge to a predetermined potential such as the power supply.

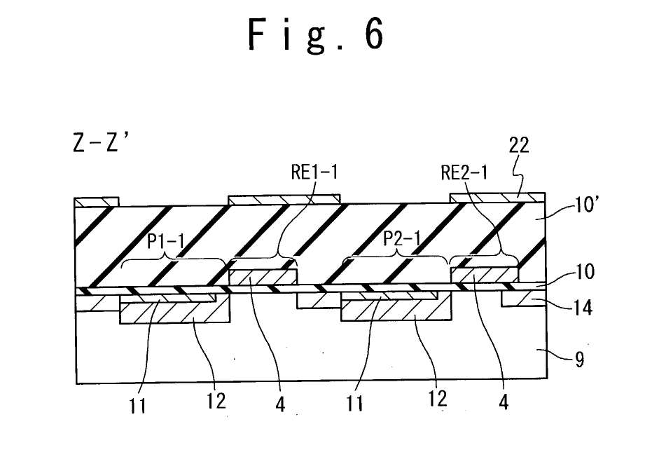

Next, the Z-Z′ section in FIG. 1 will be described with reference to FIG. 6A.

FIG. 6A is a diagram showing the structure of the Z-Z′ section in FIG. 1, i.e., the section from the image element P1-1 to the read gate RE1-1. In this case, the section from the image element 2-1 to the read gate RE2-1 is also the same as FIG. 6A.

It is composed of the image element P1-1, the read gate RE1-1, the image element P2-1, and the read gate RE2-1. The image element P1-1 and the read gate RE1-1 are as described above. The image element P2-1 and the read gate RE2-1 are the same as the image element P1-1 and the read gate RE1-1, respectively. The P⁺-type diffusion layer 14 is provided between the image element P2-1 and the read gate RE2-1 (which is not used as the charge-coupled element) and functions as a channel stopper to separate them.

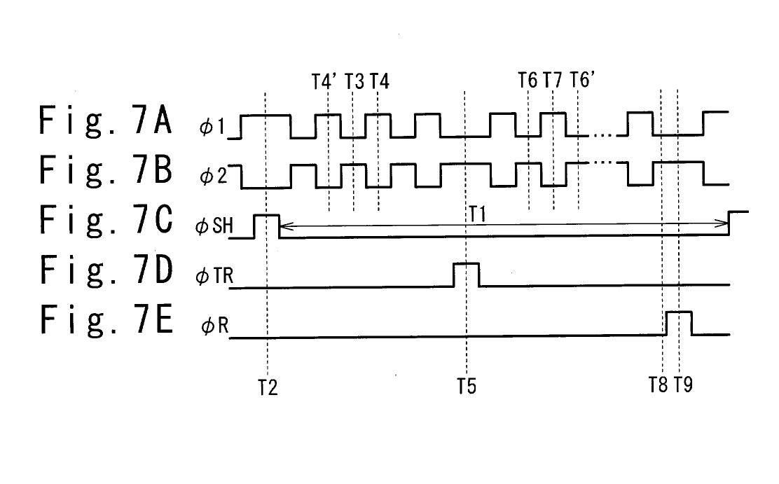

Next, the operation of the color image sensor according to the first embodiment of the present invention, i.e., a method of driving the color image sensor will be described with reference to FIG. 1 to FIG. 5C, and FIG. 7. Here, the operation when a 2-dimensional color printed image is read using the color image sensor described above will be described.

Here, FIGS. 7A to 7E are timing charts showing an example of the voltage pulses. FIG. 7A shows the voltage pulse φ₁, FIG. 7B shows the voltage pulse φ₂, FIG. 7C shows the voltage pulse φ_{SH}, FIG. 7D shows the voltage pulse φ_{TR} and FIG. 7E shows the voltage pulse φ_{R}. In this case, the present invention is not limited to the timing charts.

The voltage pulse φ₁ and the voltage pulse φ₂ as charge transfer signals are supplied to the vertical scanning charge-coupled elements of each of the vertical scanning charge transfer sections V1 to v4 and the horizontal scanning charge-coupled elements of the horizontal scanning charge transfer section H to transfer the electric charge into the direction of the vertical scanning and the direction of the horizontal scanning. The voltage pulse φ_{SH} as a first transfer signal is supplied to each of the read gates RE1-1 to RE3-4 to read the electric charges from a corresponding one of the image element P1-1 to P3-4 to a corresponding one of the vertical scanning charge transfer sections V1 to V4. The voltage pulse φ_{TR} as a second transfer signal is supplied to the transfer switches TS1 to TS4 to read the electric charges from the vertical scanning charge transfer sections V1 to V4 to the horizontal scanning charge transfer section H. The voltage pulse φ_{R} is supplied to the reset gate RS1 to RS4 to discharge unnecessary electric charges remained in the termination sections of the vertical scanning charge transfer sections.

FIGS. 2B and 2C show the movement of electric charge in the image element and the read gate shown in FIG. 2A at times T1 and T2 shown in FIG. 7. FIG. 3B to 3D show the movement of electric charge in the vertical scanning charge-coupled elements shown in FIG. 3A at times T3 to T5 shown in FIG. 7. FIGS. 4B and 4C show the movement of electric charge in the vertical scanning charge-coupled elements shown in FIG. 4A at times T6 and T7 shown in FIG. 7. FIGS. 5B and 5C show the movement of electric charge in the reset switch and reset drain shown in FIG. 5A at times T8 and T9 shown in FIG. 7. In each diagram, the vertical axis shows the depth of the potential well and the horizontal axis shows each element of the corresponding diagram.

Next, the operation of the color image sensor will be described. It should be noted that the movement of the electric charge in the image element P1-4 is shown as an example but the same operation is carried out in the image elements P2-4 to P4-4 in the same way.

(1) Step S01

The reflected light (hν) when white light is irradiated to a printed image is incident on the image element P1-4. The image element P1-4 generates electrons (electric charge) in response to the incident light. Referring to FIGS. 7C and 2B, the period of T1 is a period during which the voltage pulse φ_{SH} is in the OFF state. Hereinafter, this period is referred to as a storage or holding time period. In this period, a quantity of electrons (electric charge) generated in the image element P1-4 increases in proportional to a quantity of the incident light. The generated electrons (electric charge) are temporarily stored or held in the N-type diffusion layer 12 of the image element P1-4. The stored electric charge is shown as electric charge Q1 in FIG. 2B.

(2) Step S02

Referring to FIG. 7C and FIG. 2C, the period corresponding to the time T2 is a period during which the voltage pulse φ_{SH} is in the ON state. Hereinafter, this period is referred to as a read time. In this period, the electric charge is transferred to the CCD-N-type well 13 under the vertical scanning charge-coupled element V1-1 and is stored there. At this time, the electric charge is proportional to the product of the incident light quantity and the storage time in the image element P1-4.

FIG. 2C shows a state that the potential of P-type substrate 9 under the read gate RE1-4 rises and the electric charge Q1′ (=Q1) is transferred as electric charge Q2 as shown by the arrow. In this case, the potential rises in the CCD-N-type well 13 under the vertical scanning charge-coupled element V1-1 through the turning on of the voltage pulse φ₁ (FIG. 7A), so that the electric charge Q1 can be easily transferred.

It should be noted that the period of the voltage pulse φ_{SH} is set such that a photodiode is not saturated.

(3) Step S03

Referring to FIGS. 7A and 7B and FIGS. 3B to 3D, at the time of T3, generally, the voltage pulse φ₁ is in the ground (GND) potential and the voltage pulse φ₂ is the voltage of 5V. The electric charge Q2′ (=Q2) in the CCD-N-type well 13 under the vertical scanning charge-coupled element V4-3 at the time of T4′ is transferred to the CCD-N-type well 13 under the vertical scanning charge-coupled element V4-4 which has the deepest potential at the time of T3. At this time, the vertical scanning charge-coupled element V4-3 is controlled based on the voltage pulse φ₁, and is same in the following description. Also, the vertical scanning charge-coupled element V4-4 is controlled based on the voltage pulse φ₂, and is same in the following description. Then, the electric charge is stored therein as electric charge Q3.

FIG. 3B shows a state in which the potential well of the N-type well 15 under the vertical scanning charge-coupled element V4-4 becomes shallow, so that electric charge Q2′ is transferred to the CCD-N-type well 13 under the vertical scanning charge-coupled element V4-4 and is stored as electric charge Q3, as shown by the arrow.

(4) Step S04

Next, at the time of T4, the voltage pulse φ₁ is in the voltage of 5V and the voltage pulse φ₂ is in the ground (GND) potential. The electric charge Q3′ (=Q3) stored in the CCD-N-type well 13 under the vertical scanning charge-coupled element V4-4 at the time of T3 is transferred to the CCD-N-type well 13 under the vertical scanning charge-coupled element V4-5 which has the deepest potential at the time of T4. Then, the transferred electric charge is stored therein as electric charge Q4.

FIG. 3C shows a state in which the potential well of the N-type well 15 of the vertical scanning charge-coupled element V4-5 becomes deep so that the electric charge Q3′ is transferred to the CCD-N-type well 13 under the vertical scanning charge-coupled element V4-5 and is stored as electric charge Q4, as shown by the arrow.

In this way, the electric charge is finally transferred to the CCD-N-type well 13 under the vertical scanning termination element V4-5 by repeating the times of T3 and T4. Even if the times of T3 and T4 are repeated after the electric charge is transferred to the CCD-N-type well 13 under the final electrode, the electric charge is not transferred to another place and stays there, as far as the voltage pulse φ_{TR} supplied to the transfer switch TS4 (or the voltage pulse φ_{R} supplied to the reset switch RS4) is a GND.

(5) Step S05

Referring to FIGS. 7A, 7B and 7D and FIG. 3D, at the time of T5, the voltage pulse φ_{TR} of the transfer switch is set to the voltage of 5V, the voltage pulse φ₂ is set to the voltage of 5V and the voltage pulse φ1 is set to the ground (GND) potential. The electric charge Q4′ (=Q4) in the CCD-N-type well 13 under the vertical scanning charge-coupled element V4-5 at the time of T4 is transferred to the CCD-N-type well 13 under the horizontal scanning charge-coupled element H1 at the time of T5. Then, the transferred electric charge is stored therein as electric charge Q5.

FIG. 3D shows a state in which the potential well of the N-type well 15 under transfer switch TS 4 becomes shallow so that the electric charge Q4′ is transferred to the CCD-N-type well 13 under the horizontal scanning charge-coupled element H8 as shown by the arrow, and stored therein as electric charge Q5.

(6) Step S06

Referring to FIGS. 7A and 7B and FIGS. 4B to 4C, the time of T6 in FIG. 7A corresponds to the time of T5 in FIG. 3D. However, in FIG. 4, Q5 in FIG. 3D is referred to as Q6 in FIGS. 7A to 7E.

At the time of T7, the voltage pulse φ₂ is set to the ground (GND) potential and the voltage pulse φ₁ is set to the voltage of 5V. The electric charge Q6 (=Q5) transferred to the CCD-N-type well 13 under the horizontal scanning charge-coupled element H8 at the time of T6 is transferred to the CCD-N-type well 13 under the horizontal scanning charge-coupled element H9 at the time of T7. Then, the transferred electric charge is stored or held therein as electric charge Q7.

FIG. 4C shows a state in which the potential well of the N-type well 15 under the horizontal scanning charge-coupled element 7 becomes shallow so that the electric charge Q6 is transferred to the CCD-N-type well 13 under the horizontal scanning charge-coupled element H9, as shown by the arrow and stored as electric charge Q7.

Subsequently to the time T7, at the time of T6′, the voltage pulse φ₂ is set to the voltage of 5V and the voltage pulse φ₁ is set to the ground potential (GND). The electric charge Q7 transferred to the CCD-N-type well 13 under the horizontal scanning charge-coupled element H3 at the time of T7 is transferred to the CCD-N-type well 13 under the horizontal scanning charge-coupled element H4 at the time of T6′. The state at this time is same as the state of step S05 shown in FIG. 4B.

By repeating the times T6′ and T7, the electric charge is transferred into the direction of the horizontal scanning. The transferred electric charge is finally subjected to an electric charge-voltage conversion in the charge detecting section and then used as an electric signal, although being not shown in this figure.

(7) Step S07

Referring to FIGS. 7A, 7B, 7C and 7E and FIGS. 5B and 5C, the electric charge Q8 transferred to the CCD-N-type well 13 under the vertical scanning termination element Vi-5 at the time of T8 is unnecessary for the period of the following voltage pulse φ_{SH}. Therefore, the vertical scanning termination element Vi-5 is set to the ground potential (GND), and the voltage pulse φ_{R} is set to the voltage of 5V at the time of T9. By this, the electric charge Q8 is discharged as electric charge Q9 to the reset drain RDi at the time of T9. Then, the electric charge Q9 is discharged through the power supply.

FIG. 5C shows a state which the potential well of the reset gate RSi becomes shallow so that the electric charge Q8′ (=Q8) is transferred to the reset drain RDi as electric charge Q9 as shown by the arrow.

In this way, when the electric charge transferred to the vertical scanning termination element Vi-5 is unnecessary, the electric charge can be discharged to the reset drain RDi by turning one the reset gate RSi shown in FIGS. 5A to 5C.

Through the above process of (1) to (7), the collection of the electric charge generated in the image elements P1-1 to P3-4 can be carried out for one period of φ_{SH}.

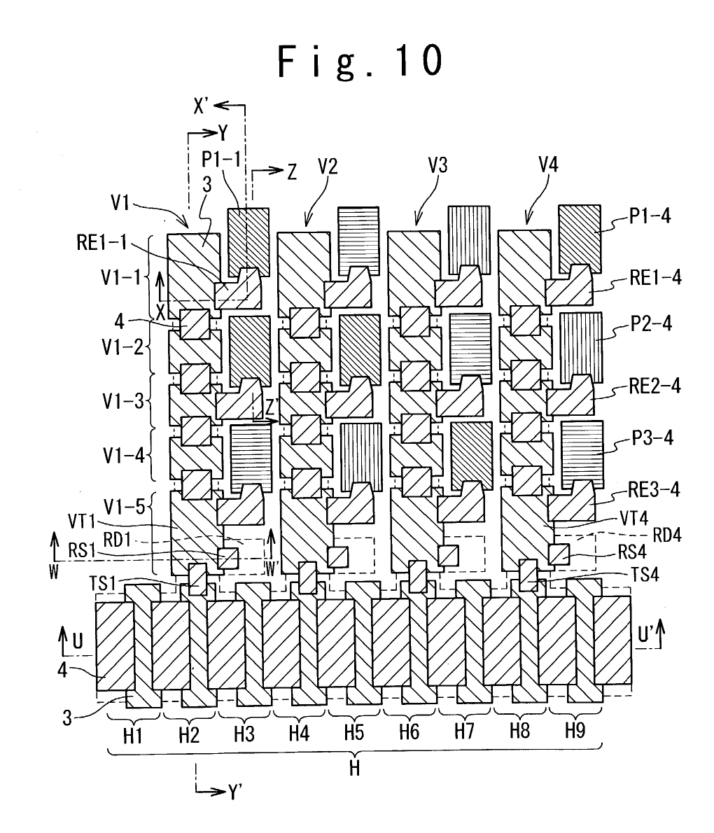

In this embodiment, different color is used for the every row of the image elements P1-1 to P3-4. However, it is not always necessary to unify the arrangement of the color filters on the image elements P1-1 to P3-4. It is possible to use any arrangement of the color filters. Such an example is shown in FIG. 10.

FIG. 10 is a plan view showing another structure of the color image sensor according to the embodiment of the present invention. By applying the voltage pulse φ_{SH} to the read gate REi-i of the image elements to be read, the electric charge can be selectively read from the image element Pi-i in accordance with the color. Because the structure and operation are same as described above except that the coloring of the image elements P1-1 to P3-4 is different in each row, the description is omitted.

Also, in this embodiment, only a case of the arrangement of three rows of the image elements P1-1 to P3-4 was described. However, the present invention can be applied to a case of four or more rows of the image elements. For example, it is possible that the fourth row is added and the row is used as the image element for white and black. By adding the white and black row, the signal-to-noise ratio in reading the white and black image can be improved.

According to the present invention, it is possible to discharge unnecessary electric charge stored in the vertical scanning termination element as the vertical scanning charge-coupled element Vi-5 such as the thermo electrons (heat noise) generated in the CCD-N-type well 13 in the vertical scanning charge transfer section V1 and electrons generated in the image element Pi-i but not transferred into the horizontal scanning charge transfer section H by using the function of the reset gate RSi and the reset drain RDi. That is, the generation of the read error due to the unnecessary electric charge can be prevented.

Also, by selecting the vertical scanning charge transfer sections Vi for the reading operation of the electric charge from among all the vertical scanning charge transfer sections 24 by turning ON/OFF of each transfer switches TSi, the number of the image elements used for the reading operation of the electric charge can be controlled. That is, the resolution of the reading operation can be freely controlled. For example, when the resolution is lowered, the high-speed process can be executed.

In the same way, by selecting the number of the image elements used for the reading operation of the electric charge from among all the image elements P1-1 to P3-4 by turning ON/OFF of each of the read gates RE1-1 to RE3-4, the resolution of the reading operation can be freely controlled.

Also, by controlling the periods of the reset gate RSi, read gate REi-i, and transfer switch TRi, the storage time of the electric charge can be controlled. That is, the reading operation speed can be controlled. Also, because the quantity of electric charge to be read (corresponding to a signal quantity of the voltage signal) can be freely controlled, the sensitivity of the color image sensor can be controlled.

Also, a process about the timings of the reading operation of the electric charge which is necessary in case that a plurality of horizontal scanning charge transfer sections H are used. However, in the present invention, the horizontal scanning charge transfer section H can be made single. Therefore, such a process becomes unnecessary and the read precision can be improved.

The voltage pulses φ₁ and φ₂ as clocks to the vertical scanning charge-coupled elements are common to those as clocks of the horizontal scanning charge-coupled elements. That is, without increasing the kind of the clocks (the voltage pulses) for the control, the vertical scanning charge transfer section can be added.

Also, by controlling the timings of the reset gate RSi, read gate REi-i, and transfer switch TSi properly, it is possible to take out an electric signal in which the data of R-G, G-B, and R-G-B are synthesized.

(Second Embodiment)

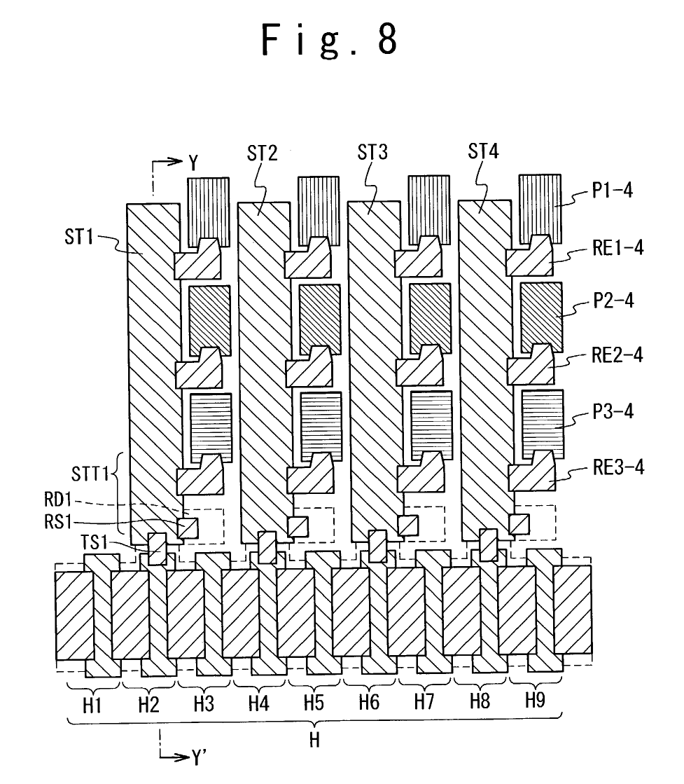

The color image sensor of according to the second embodiment of the present invention will be described with reference to FIG. 8. FIG. 8 is a plan view showing the structure of the color image sensor according to the second embodiment of the present invention. The color image sensor is composed of image elements P1-1 to P1-4 of the first row to the image elements P3-1 to P3-4 of the third row, the read gates RE1-1 to RE3-4 corresponding to the image element P1-1 to P3-4, storage gates V1 to V4 as vertical scanning charge transfer sections, the horizontal scanning charge transfer section H, reset gates RSi, reset drains RDi and transfer switches TSi. The color image sensor in this embodiment is formed on the P-type substrate.

This embodiment is different from the first embodiment in the point that the vertical scanning charge transfer sections V1 to V4 having the plurality of the vertical scanning charge-coupled elements are used in the first embodiment whereas single storage gates 19 are used in the second embodiment. By using the single storage gate, the plurality of wiring lines for the voltage pulse φ₁ and the voltage pulse φ₂ to the plurality of vertical scanning charge-coupled elements can be made single. Also, the area of the CCD-N-type well 13 can be decreased, as described later. Therefore, the generation of thermo electrons (thermal noise) can be reduced.

Also, if the potentials are set to be higher in order from the image element to the horizontal scanning charge-coupled element, the storage gate can be formed from two or more gates.

The storage gate 19 carries out a charge transfer in the direction orthogonal to the horizontal scanning charge transfer section H, stores or holds an electric charge temporarily and outputs the electric charge to the horizontal scanning charge transfer section H. The electric charge is stored in a storage gate termination section 19′ of the storage gate 19 in the neighborhood of the transfer switch TSi. The storage gate 19 is connected with the horizontal scanning charge transfer section H via the transfer switches TSi.

The other structural components are same as those of the first embodiment and the description of them is omitted.

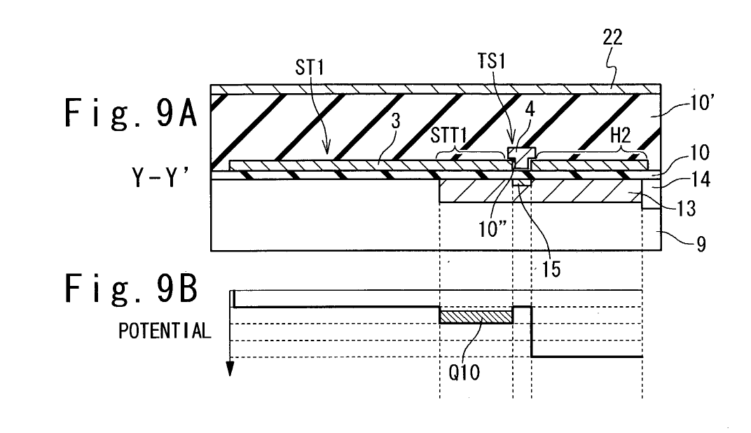

Next, the cross section along the line Y-Y′ shown in FIG. 8 will be described with reference to FIG. 9A. FIG. 9A is a cross section view of the color image sensor along the line Y-Y′ in FIG. 8, i.e., showing the structure of the cross section from the storage gate 19 to the horizontal scanning charge transfer section H. The cross section has the storage gate 19, the horizontal scanning charge-coupled element H2i, and the transfer switch TSi. The surface is covered by the oxide film 10′ functioning as a passivation film and a light shielding film 22 formed on the oxide film 10′.

The storage gate STi is connected with the read gates REi-1 to REi-3. The storage gate STi receives the electric charges from in the image elements Pi-1 to Pi-3 through the read gates REi-1 to REi-3 and transfers the received electric charges to the horizontal scanning charge transfer section H. The storage gate STi has the oxide film 10, a first layer polysilicon electrode 3 and a CCD-N-type well 13.

The CCD-N-type well 13 is provided to have a predetermined depth in the depth direction of a P-type substrate 9 and to have a predetermined area in the transversal direction parallel to the surface of the P-type substrate 9. However, the CCD-N-type well 13 is formed from the neighborhood of the horizontal scanning charge transfer section H to the neighborhood of the read gate REi-4, and the storage gate termination section 19′ is formed in the neighborhood of the read gate REi-4.

The first layer polysilicon electrode 3 is formed to cover the surface of the CCD-N-type well 13 with a predetermined film thickness and to extend into the direction orthogonal to the horizontal scanning charge transfer section H in the surface of the oxide film 10 which covers the top of P-type substrate 9. The first layer polysilicon electrode 3 is arranged in parallel to the column of the image elements Pi-1 to Pi-3. A part of the first layer polysilicon electrode 3 is covered by a second layer polysilicon electrode 4 for the transfer switch TSi through the oxide film 10″. The other structural components are same as those of the first embodiment 1. Therefore, the description of them is omitted.

Next, the operation of the color image sensor according to the second embodiment of the present invention or a driving method of color image sensor will be described. It should be noted that the movement of the electric charge in the image elements P1-1 to P1-3 is shown as an instance and the operation will be described.

FIG. 9B shows the storage and movement of the electric charge at elements shown in FIG. 9A at the time T2 shown in FIGS. 7A to 7E. The vertical axis shows the depth of the potential well and the horizontal axis shows the elements in FIG. 9A.

In the operation of the second embodiment, the electric charge is read from the image elements P1-1 to P1-3 as shown in FIG. 9B and is immediately stored in the CCD-N-type well 13 under the storage gate STi nearly the transfer switch TSi. That is, FIG. 3C of the step S03 and FIG. 3B of step S04 in the first embodiment correspond to FIG. 9B. In this case, at the time of T2, the voltage pulse φ_{SH} is turned on so that the potential well of the read gates RE1-1 to RE1-3 becomes deep. Consequently, the transfer of the electric charges stored in the image elements P1-1 to P1-3 becomes possible. Also, the voltage pulse φ₁ (only the voltage pulse φ₁ is applied to the first layer polysilicon electrode 3 of the storage gate ST1 in this embodiment) is turned on so that the potential well of the storage gate ST1 becomes deep. As a result, the storage gate ST1 becomes possible to receive the electric charge. Then, the electric charge is transferred to the storage gate.

By applying the voltage pulse φ_{TR} to transfer switch TS1, the electric charge stored in the storage gate ST1 can be selectively transferred to the horizontal scanning charge transfer section H, like FIG. 3C of the step S05 in the first embodiment. Or, by applying the voltage pulse φ_{R} to the reset gate RS1, the stored electric charge can be selectively reset (discharged to the reset drain RD1), like FIG. 5C of the step S07 in the first embodiment.

The other operation is same as in the first embodiment. Therefore, the description is omitted.

In this embodiment, the same effect as the first embodiment can be obtained. Also, the structure of the storage gate as the vertical scanning charge transfer section can be made simple, and the manufacturing yield can be improved. Also, it is possible to decrease the clock or voltage pulse for the vertical scanning charge transfer section to one.

According to the present invention, the unnecessary electric charge stored in the element can be discharged and the control of the density of the read image (the resolution) becomes possible.

What is claimed is:

1. A color image sensor comprising:
a plurality of image elements, which are arranged in a matrix of rows and columns and each of which generates an electric charge in response to incidence of light;
a plurality of read gate sections, which are provided for said plurality of image elements and each of which controls transfer of said electric charge generated in a corresponding one of said plurality of image elements;
a plurality of vertical scanning charge transfer sections, each of which is provided for every column of said matrix and holds and transfers said electric charges transferred from a corresponding column of said plurality of read gate sections;
a plurality of transfer switch sections, each of which is provided for a termination section of a corresponding one of said plurality of vertical scanning charge transfer sections and controls transfer of said electric charges from the corresponding vertical scanning charge transfer section; and
a horizontal scanning charge transfer section which is provided for said plurality of transfer switch sections and holds and transfers said electric charges transferred from said plurality of vertical scanning charge transfer sections via said plurality of transfer switch sections.

2. The color image sensor according to claim 1, wherein each of said plurality of vertical scanning charge transfer sections comprises:
a plurality of first charge transfer sub-sections, each of which is provided for a corresponding one of said plurality of read gate sections for one column corresponding to said vertical scanning charge transfer section, and stores and transfers said electric charge; and
a plurality of second charge transfer sub-sections, each of which is provided between adjacent two of said plurality of first charge transfer sub-sections, and transfers said electric charge transferred from one of said adjacent two and transfers to the other of said adjacent two, and
wherein one of said plurality of first charge transfer sub-sections corresponding to said termination section is larger in area than remaining ones of said first charge transfer sub-sections.

3. The color image sensor according to claim 1, wherein each of said plurality of vertical scanning charge transfer sections comprises:
a plurality of first charge transfer sub-sections, each of which is provided for a corresponding one of said plurality of read gate sections for one column corresponding to said vertical scanning charge transfer section, and stores and transfers said electric charge; and
a plurality of second charge transfer sub-sections, each of which is provided between adjacent two of said plurality of first charge transfer sub-sections, and transfers said electric charge transferred from one of said adjacent two and transfers to the other of said adjacent two, and
wherein said plurality of first charge transfer sub-sections and said plurality of second charge transfer sub-sections transfer said electric charges based on a 2-phase charge transfer signal.

4. The color image sensor according to claim 1, further comprising:
a plurality of reset sections which are respectively provided for said termination sections of said plurality of vertical scanning charge transfer sections, and each of which discharges said electric charge in a corresponding one of said plurality of vertical scanning charge transfer sections.

5. The color image sensor according to claim 4, wherein each of said plurality of reset sections discharges said electric charge remained in a corresponding one of said plurality of termination sections, immediately before said electric charge is newly transferred to said corresponding termination section of said corresponding vertical scanning charge transfer section, after said electric charge held in said corresponding termination section of said corresponding vertical scanning charge transfer section is transferred to said horizontal scanning charge transfer section.

6. The color image sensor according to claim 5, wherein each of said plurality of reset sections comprises a reset gate and a reset drain, and
said reset drain is connected with a predetermined potential.

7. The color image sensor according to claim 2, wherein said first charge transfer section in said termination sub-section for every column has a larger capacity for holding of said electric charge than that of the other of said first charge transfer sub-sections.

8. The color image sensor according to claim 2, wherein said first charge transfer sub-section in said termination section for every column can hold said electric charge generated by said plurality of image elements for the corresponding column.

9. The color image sensor according to claim 3, wherein said horizontal scanning charge transfer section comprises:
a plurality of first main charge transfer sections provided for said plurality of transfer switch sections to hold and transfer said electric charge; and
a plurality of second main charge transfer section, each of which is provided between adjacent two of said plurality of first main charge transfer sections to hold said signal charge transferred from one of said adjacent two and to transfer to the other of said adjacent two,
wherein said plurality of first main charge transfer sections and said plurality of second main charge transfer section transfer sections transfer said electric charge based on a 2-phase transfer signal, and
said plurality of first charge transfer sub-sections and said plurality of second charge transfer sub-sections transfer said electric charges based on said charge transfer signals common to said first main charge transfer section and said second main charge transfer section, respectively.

10. The color image sensor according to claim 1, wherein said plurality of transfer switch sections selects one of said plurality of vertical scanning charge transfer sections for said charge to be transferred from.

11. The color image sensor according to claim 1, wherein each of said plurality of read gate sections controls a holding time of said electric charge by the corresponding image element.

12. The color image sensor according to claim 1, wherein said vertical scanning charge transfer section has a first well which holds said electric charge, and
said horizontal scanning charge transfer section has a second well which holds said electric charge,
said first well and said second well are formed as a unit.

13. A method of driving a color image sensor, comprising the steps of:
(a) storing electric charge generated based on incident light by a plurality of image elements in a matrix;
(b) storing said electric charges transferred from a column of said matrix of said plurality of image elements by a corresponding one of a plurality of vertical scanning charge transfer sections; and
(c) converting said electric charges transferred from said plurality of vertical scanning charge transfer sections into an electric signal by a horizontal scanning charge transfer section.

14. The method of driving a color image sensor according to claim 13, wherein said (b) step comprises the step of:
(d) receiving said electric charges transferred from each of the columns of said plurality of image elements based on a first transfer signal by a corresponding one of said plurality of vertical scanning charge transfer sections, and
a storage time of said electric charge in each of said plurality of image elements is controlled based on a period of said first transfer signal.

15. The method of driving a color image sensor according to claim 13, wherein said (c) step comprises the step of:
(e) receiving said electric charges transferred from said plurality of vertical scanning charge transfer sections based on a second transfer signal by said horizontal scanning charge transfer section, and
one of said plurality of vertical scanning charge transfer sections for said electric charge to be transferred from is selected based on said second transfer signal.
